(19) United States
(12) Patent Application Publication
(10) Pub. No.: US 2026/0353534 A1
(43) Pub. Date: Nov. 5, 2026

(54) DETECTING A LEAKAGE CURRENT

(71) Applicant: SIGNIFY HOLDING B.V., Eindhoven (NL)

(72) Inventors: Liang SHI, Shanghai (CN); Gang WANG, Shanghai (CN); Kang LI, Shanghai (CN)

(21) Appl. No.: 19/486,431

(22) PCT Filed: May 14, 2024
(86) PCT No.: PCT/EP2024/063146

§ 371 Date: Nov. 21, 2025

(30) Foreign Application Priority Data
May 23, 2023 (WO) PCT/CN2023/095826
Jun. 20, 2023 (EP) 23180284.4

(51) Int. Cl. H05B 45/50; G01R 31/52

(52) U.S. Cl. CPC H05B 45/50; G01R 31/52

(57) ABSTRACT

A mechanism for detecting a fault in an LED lighting arrangement. A monitoring device is configured to monitor a sensed leakage signal through a grounding circuit of the LED driver for the LED lighting device. The monitoring device is configured to determine or predict the presence or absence of a fault in the LED lighting arrangement responsive to the sensed leakage signal. The grounding circuit comprises a Y-capacitor (C_{γ}) connected to the converter and for connection with the protective earth and adapted to improve robustness of the LED driver to electromagnetic interference.

### FIELD OF THE INVENTION

The present invention relates to the field of LED lighting, and in particular to LED drivers for LED lighting arrangements.

### BACKGROUND OF THE INVENTION

There is an increasing demand for reliable LED lighting. In particular, outdoor lighting is becoming increasingly popular. It is advantageous if LED luminaires for use in outdoor environments are waterproofed, to reduce a likelihood of water infiltration into the luminaire, which would otherwise cause damage to luminaire components. If there is a failure of the waterproof protection, then infiltrating water can reduce an efficiency of the luminaries and may even create a safety issue.

There is therefore a desire to improve a detection of a fault in an LED lighting arrangement of an LED luminaire, particularly those attributable to water ingress.

JP 2010/110089 A2 discloses a circuit that detects a leakage current through a Y-cap to determine a fault of the Y-cap.

U.S. Pat. No. 9,621,024B2 discloses detecting a current flowing through a ground fault detection element, in the driver, connected to ground and determining a grould fault at the LED accordingly.

### SUMMARY OF THE INVENTION

Y-capacitors (or simply Y-caps) have been widely used to improve robustness of the LED driver to electromagnetic interference. The underlying idea of the present invention is to monitor for changes in a leakage current through a grounding Y-capacitor circuit of an LED driver to remotely detect the occurrence of a fault in an LED lighting arrangement driven by the LED driver. It has been recognized that such a fault will cause changes to the leakage current in such a ground circuit, e.g., through the Y-capacitor of the LED driver. In particular, a fault resulting from water ingress will likely introduce a short in the LED lighting arrangement to the ground, through which at least some current will leak. The ground leakage current in the LED lighting arrangement has a corresponding effect on the ground leakage current in the LED driver driving the LED lighting arrangement. More specially, the ground leakage current in the Y-capacitor of the LED driver is diverted by the ground leakage current in the LED lighting arrangement, thus the ground leakage current in the LED driver is reduced. By monitoring for changes in the leakage current in the LED driver, a fault in the LED lighting arrangement can therefore be detected.

A detected presence or absence of a fault can be used to control the operation of the LED driver, e.g., to reduce or deactivate an output voltage when a fault is occurred. This can improve the safety of the LED lighting arrangement and/or improve component lifespan.

The invention is defined by the claims.

According to examples in accordance with an aspect of the invention, there is provided an LED driver for use with an LED lighting arrangement.

The LED driver comprises: an input interface configured to receive an input power; a converter configured to convert the input power into an output power; an output interface configured to connect to the LED lighting arrangement and to, when connected, provide the output power to the LED lighting arrangement; a grounding circuit adapted to connect the converter to a protective earth; and a sensing circuit adapted to sense a leakage signal, from the converter to the protective earth, through the grounding circuit;

The LED driver further comprises a monitoring device adapted to determine the presence or absence of a fault at the LED lighting arrangement responsive to the sensed leakage signal sensed by the sensing circuit.

The grounding circuit comprises a Y-capacitor connected to the converter and for connection with the protective earth. Y-capacitors (or simply Y-caps) have been widely used to improve robustness of the LED driver to electromagnetic interference, and the present embodiment re-uses the Y-cap in detecting a fault in the LED lighting arrangement.

The present disclosure provides a technique for detecting, in the LED driver, the presence of a fault at the LED lighting arrangement. In particular, if a fault occurs at the LED lighting arrangement, then the magnitude and/or pattern of the leakage signal through the grounding circuit of the LED driver will change. If there is a short between a protective earth and circuitry in the LED lighting arrangement, then a current will leak from the LED lighting arrangement. This changes the characteristics of the leakage current through the grounding circuit in the LED driver. It has been recognized that this change in characteristics can be identified and used to recognize or characterize the occurrence of a fault. The advantage of this technique is that it does not need the LED lighting arrangement to have an active circuit to actively communicate this presence or absence of a fault to the LED driver.

In one embodiment, the monitoring device is adapted to determine the presence of a protective earth leakage fault occurring at the LED lighting arrangement responsive to the amplitude of the sensed leakage current being lower than a first threshold; and is adapted to determine the absence of a protective earth leakage fault occurring at the LED lighting arrangement responsive to the amplitude of the sensed leakage current being greater than the first threshold.

In this way, the monitored amplitude of the leakage current downwardly breaching a threshold triggers the identification that a fault has occurred. In particular, it has been recognized that a decrease in the amplitude of the leakage current in the LED driver implies the presence of a leakage current elsewhere (i.e., in the LED lighting arrangement). As the presence of another leakage current implies the occurrence of a fault, it is possible to identify the presence of a fault when the amplitude monitored leakage current drops below a threshold.

Use of a threshold allows for noise in the leakage current to be ignored.

In some examples, the first threshold is a percentage of the leakage signal flowing, from the converter to the protective earth, through the grounding circuit in the absence of protective earth leakage fault occurring at the LED lighting arrangement. This allows the first threshold to be adaptively/dynamically adapted for the variable specific use case of the LED driver, which may depend upon the variable demands of the LED lighting arrangement and/or a variable desired power to be drawn by the LED lighting arrangement (e.g., to achieve a particular dimming level). This approach can thereby dynamically adapt the first threshold to the normal operating parameters of the LED driver and/or LED lighting arrangement.

Preferably, the percentage is no more than seventy percent. This reduces a risk that a noise in the leakage signal will unintentionally trigger the (false) identification of a fault in the LED lighting arrangement. Thus, a false positive rate of identifying the presence of a fault is decreased.

In some examples, the monitoring device is configured to: monitor an amplitude of the output power; and the monitoring device is configured to determine the presence of the fault occurring at the LED lighting arrangement responsive to the sensed leakage current being lower than the first threshold and responsive to the output power remains stable. This example avoids a false identification caused by varying ground leakage current due to varying output power even when the LED lighting arrangement is intact, instead of due to varying ground leakage current in the LED lighting arrangement due to the occurrence of a fault.

The monitoring device may be adapted to determine the presence or absence of the fault at the LED lighting arrangement responsive to a peak value of the leakage signal sensed by the sensing circuit. In other words, the amplitude of the sensed leakage signal may be the peak value of the sensed leakage signal (e.g., within a moving window). This peak value may, for instance, be compared to the threshold to determine or detect the presence or absence of the fault, using any previously described approach. The advantage of this embodiment is that the peak value is relatively easier to detect since the leakage signal may be a high frequency signal. Alternatively, another value, such as such an average value and/or RMS value, could be used.

The sensing circuit may comprise a sensing resistor connected between the converter and the protective earth, wherein a voltage across the sensing resistor defines the leakage current. This provides an approach for producing a signal responsive to the leakage current using simple and low-cost components.

The sensing resistor preferably has a low impedance, e.g., a resistance of less than 100 Ω, e.g., less than 50 Ω or less than 20 Ω. This reduces power loss.

The sensing circuit may further comprise an operational amplifier configured to amplify a first voltage signal, being the voltage across the sensing resistor, to indicate the leakage current. This allows for the relatively low amplitude leakage current to be more accurately identified.

To facilitate the above detection technique, there is also proposed an LED lighting arrangement for use with any herein descried LED driver. The LED lighting arrangement is adapted to be placed in proximity with an external grounding structure which is to be connected to the protective earth. The proposed LED lighting arrangement is specially designed to allow or even exaggerate (i.e., enhance the effect of) a ground leakage current when a fault occurs at the LED lighting arrangement.

More specifically, the LED lighting arrangement comprises: an LED array comprising one or more LEDs, and an LED input interface connected to said LED array and configured to connect to the output interface of the LED driver.

The LED lighting arrangement also comprises an electricity leaking structure electrically connected to the LED input interface, said electricity leaking structure being adapted to electrically connect the LED input interface to the external grounding structure, to thereby leak a signal to said external grounding structure, upon a fault at the LED lighting arrangement.

The LED lighting arrangement thereby provides an electricity leaking structure that, when a fault occurs, leaks a current to the external grounding structure. This affects a current leaking at the LED driver connected to the LED lighting arrangement, which current can therefore be detected by the monitoring device of the LED lighting arrangement. The proposed LED lighting arrangement thereby provides a suitable lighting arrangement for use with the proposed LED driver.

The LED lighting arrangement may further comprise a substrate configured to carry the LED array, wherein the electricity leaking structure comprises one or more conductive pads formed on the substrate.

Preferably the one or more conductive pads are positioned along at least one edge. For instance, the one or more conductive pads may comprise a plurality of pads positioned along one or more edges of the substrate. Upon water ingress, the water is likely to be accumulated at the edges and electrically contacts the conductive pads at the edges, thus this approach facilitates identification of water ingress along any of the one or more edges.

More preferably the one or more conductive pads are positioned along a perimeter of the substrate. For instance, the one or more conductive pads may comprise a plurality of pads positioned along one or more edges of the substrate. This approach facilitates identification of water ingress towards the LED array from any direction.

The electricity leaking structure may be configured to electrically connect the LED input interface to the external grounding structure by an ingress of water or moisture accumulated at and contacting the electricity leaking structure and the external grounding structure.

In some examples, the substrate comprises a conductive core configured to connect, in use, to the external grounding structure; and the electricity leaking structure is configured to electrically connect the input interface to the conductive core upon a fault at the LED lighting arrangement.

The LED input interface may comprise a positive terminal and a negative terminal. The electricity leaking structure, e.g., each conductive pad thereof, may be electrically connected to either the positive terminal or the negative terminal.

There is also provided a luminaire comprising any herein disclosed LED driver and any herein disclosed LED lighting arrangement. In preferred examples, the luminaire also comprises a luminaire housing configured to act as the external grounding structure, wherein the grounding circuit of the LED driver is connected to the luminaire housing.

These and other aspects of the invention will be apparent from and elucidated with reference to the embodiment(s) described hereinafter.

### BRIEF DESCRIPTION OF THE DRAWINGS

For a better understanding of the invention, and to show more clearly how it may be carried into effect, reference will now be made, by way of example only, to the accompanying drawings, in which:

FIG. 1 is a circuit diagram illustrating a lighting system;

FIG. 2 is a circuit diagram illustrating an LED lighting arrangement;

FIG. 3 illustrates a lighting arrangement; and

FIG. 4 illustrates a luminaire.

### DETAILED DESCRIPTION OF THE EMBODIMENTS

The invention will be described with reference to the Figures.

It should be understood that the detailed description and specific examples, while indicating exemplary embodiments of the apparatus, systems and methods, are intended for purposes of illustration only and are not intended to limit the scope of the invention. These and other features, aspects, and advantages of the apparatus, systems and methods of the present invention will become better understood from the following description, appended claims, and accompanying drawings. It should be understood that the Figures are merely schematic and are not drawn to scale. It should also be understood that the same reference numerals are used throughout the Figures to indicate the same or similar parts.

The invention provides a mechanism for detecting a fault in an LED lighting arrangement. A monitoring device is configured to monitor a sensed leakage signal through a grounding circuit of the LED driver for the LED lighting device. The monitoring device is configured to determine or predict the presence or absence of a fault in the LED lighting arrangement responsive to the sensed leakage signal.

Embodiments are based on the realization that a fault in the LED lighting arrangement will change the characteristics of a leakage signal through a grounding circuit of the LED driver for said LED lighting arrangement. In particular, a grounding fault or protective earth fault will result in a current leaking within the LED lighting arrangement, which has a knock-on effect to a leakage current for the LED driver.

Proposed approach can be employed in any form of lighting system or luminaire, such as those for industrial, domestic and/or clinical lighting environments. Embodiments are particularly advantageous for lighting scenarios that are exposed to external environments, such as outdoor settings.

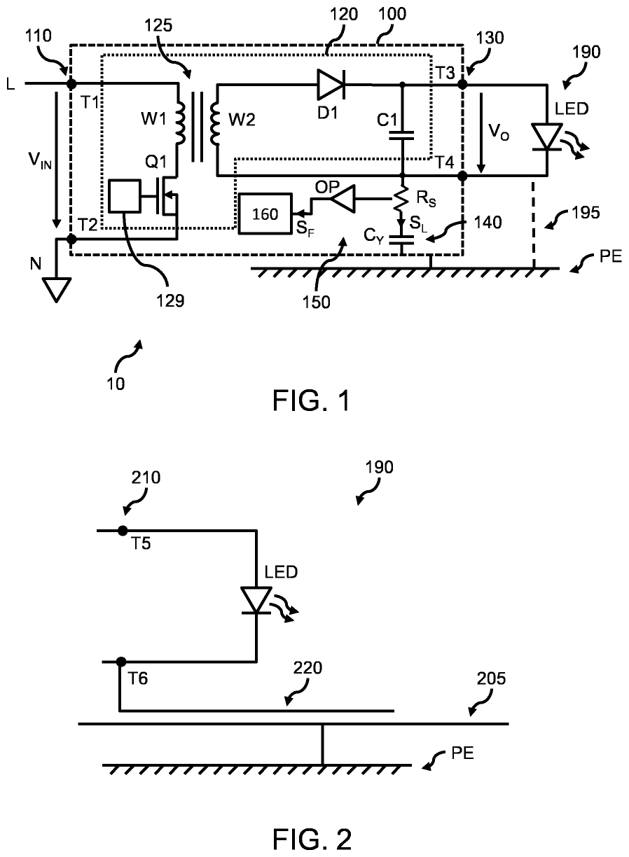

FIG. 1 illustrates a lighting system 10 comprising a proposed LED driver 100. The LED driver 100 is configured to drive or power an LED lighting arrangement 190, which may form part of the lighting system.

The LED lighting arrangement 190 comprises an LED array LED comprising one or more LEDs, e.g., a plurality of LEDs. A proposed LED lighting arrangement that is particularly advantageous is described later in this disclosure.

The LED driver 100 comprises an input interface 110 configured to receive an input power V_{IN}. In the illustrated example, the input interface comprises a pair T1, T2 of input terminals.

In the illustrated example, the input power V_{IN} is an AC input power, e.g., between a line voltage L and a neutral voltage N. The line voltage may, for instance, be of a mains power supply, and the neutral voltage may similarly be of the mains power supply. Alternatively, the input power V_{IN} may be a DC power, such as that provided by a battery or cell arrangement or by a rectifying arrangement (e.g., rectifying a mains power supply).

The LED driver also comprises a converter 120 configured to convert the input power V_{IN} into an output power V_{O}.

The illustrated converter 120 takes the form of a flyback converter comprising a transformer 125 formed from a primary winding W1 and a secondary winding W2. The primary winding W1 is connected in series with a switch. The conductivity of the switch is controlled by a switch controller 129. The secondary winding W2 is connected in series with a rectifying diode D1 and an output capacitor C1. A voltage across the output capacitor C1 defines the output power V_{O}. The operation and control of a flyback converter (e.g., using the switch controller 129) is well known in the art, and is not described for the sake of conciseness.

Although illustrated as a flyback converter, the converter 120 may be replaced by any other suitable form of converter or driving circuitry. For instance, the converter may instead be a buck converter, a boost converter, a (different) buck-boost converter or a Ćuk converter. Other suitable examples will be apparent to the skilled person.

The LED driver 100 also comprises an output interface 130 configured to connect to the LED lighting arrangement 190. When connected to the LED lighting arrangement, the output interface provides the output power to the LED lighting arrangement. In the illustrated example, the output interface comprises a pair T3, T4 of output terminals. The voltage across the output terminals is the output voltage V_{O} of the converter 120.

The LED driver also comprises a grounding circuit 140 adapted to connect the converter to a protective earth PE. In the illustrated example, the grounding circuit 140 comprises a Y-capacitor C_{Y} connected to the converter and for connection with the protective earth. In particular, the Y-capacitor is connected to a return line of the converter 120, e.g., which return line is used for returning current flow from the LED lighting arrangement 190 back to the input interface 110. Use of a Y-capacitor in this way is known to improve the EMI performance of an LED driver. In a practical product, the Y-capacitor is often connected to the housing of the LED driver internally in the LED driver, which housing is schematically illustrated used a dashed dash line, the housing of the LED driver may be connected to a housing of a luminaire which is connected to the protective earth PE.

The LED driver 100 also comprises a sensing circuit 150 adapted to sense a leakage signal S_{L}, from the converter to the protective earth, through the grounding circuit. The leakage signal S_{L} therefore represents a current flow through the grounding circuit. Thus, the sensing circuit 150 monitors the leakage current S_{L} and may generate a feedback signal S_{F} that responds or indicates the (magnitude of the) leakage current S_{L}.

In the illustrated example, the sensing circuit 150 comprises a sensing resistor R_{S} connected in series with the Y-capacitor C_{Y} of the grounding circuit. A voltage across the sensing resistor R_{S} will thereby change responsive to the (magnitude of the) leakage signal through the ground circuit. The voltage across the sensing resistor R_{S} may therefore represent the sensed leakage signal, e.g., may define a feedback signal S_{F}.

Preferably, the size of the sensing resistor is small, e.g., less than 100 Ω, e.g., less than 50 Ω, e.g., less than 20 Ω. This reduces a risk of heating by the sensing resistor and/or power loss in the LED driver 100.

In some examples, the sensing circuit 150 further comprises an operational amplifier OP configured to amplify a first voltage signal, being the voltage across the sensing resistor. The amplified first voltage signal may represent the feedback signal S_{F} that indicates the leakage current.

In some examples, the grounding circuit 140 comprises a further Y-capacitor (not shown) connected in parallel to the series connection of the Y-capacitor C_{Y} and the sensing circuit. This advantageously increases the EMI performance of the LED driver 100 whilst still facilitating the sensing of any changes to a leakage current.

The LED driver 100 also comprise a monitoring device 160 adapted to determine the presence or absence of a fault at the LED lighting arrangement responsive to the sensed leakage signal sensed by the sensing circuit. In particular, it has been herein recognized that a fault in the LED lighting arrangement will cause a detectable change or difference to the leakage signal that flows through the grounding circuit 140. Thus, it is possible to determine or detect the presence or absence of a fault in the LED lighting arrangement by monitoring the current through the grounding circuit.

Information on the detected presence or absence of a fault in the LED lighting arrangement 190 can be used to control the operation of the LED driver. For instance, the LED driver may be configured to stop providing the output voltage (e.g., deactivate the converter) responsive to the detected presence of a fault. This can be performed by the monitoring device communicating the detected presence of a fault to the switch controller 129, which stops a switching operation (thereby deactivating the converter) responsive to the detected presence of a fault. This can reduce a risk of damage to the LED lighting arrangement and/or injury to an operator of, or other individual in the vicinity of, the LED lighting arrangement.

Other techniques for controlling a converter responsive to a detected presence or absence of a fault of an LED lighting arrangement will be apparent to the skilled person.

In some examples, the monitoring device 160 is configured to determine the presence of a protective earth leakage fault occurring at the LED lighting arrangement responsive to the amplitude of the sensed leakage current being lower than a first threshold. Similarly, the monitoring device 160 may be configured to determine the absence of a protective earth leakage fault occurring at the LED lighting arrangement responsive to the amplitude of the sensed leakage current being greater than the first threshold.

This embodiment recognizes that is a leakage current drops in amplitude, then there is likely to be a current flow 195 (to the protective earth) in the LED lighting arrangement due to a fault at the LED lighting arrangement. More particularly, a fault in the LED lighting arrangement (such as a water leakage) may short the return path of the LED lighting arrangement to the protective earth. Thus, a path taken by a noise or leakage signal passes through this new short. A change in the leakage signal through the grounding circuit may thereby indicate the presence of a fault (e.g., water ingress) at the LED lighting arrangement. Please note that, there may be a nominal leakage current at the LED lighting arrangement due to parasitic leakage even when there is no fault, and this nominal leakage current should be excluded or considered separately from the current flow 195 resulting from a fault. The following description will ignore this nominal leakage current.

The first threshold may, for instance, be a percentage of the (e.g., average) leakage signal flowing, from the converter to the protective earth, through the grounding circuit in the absence of protective earth leakage fault occurring at the LED lighting arrangement. In this way, the monitoring device 160 may be adapted to identify or detect a substantially large change in the leakage current, which may indicate the presence of a fault.

The percentage may, for instance, be no more than seventy percent, e.g., no more than fifty percent. In some examples, the percentage is no less than twenty percent, e.g., no less than forty percent. This example percentages provide a good range of values that are robust against noise, whilst still being able to detect faults that cause only a small drop in the leakage current.

The amplitude of the sensed leakage current may be defined as the peak value/amplitude of the sensing current, e.g., within a certain moving time window, as defined by the feedback signal S_{F}. Thus, the peak value/amplitude (e.g., within a moving time window) may be compared to the (first) threshold to determine or predict whether or not there is a protective earth leakage fault at the LED lighting arrangement. This threshold may, for instance, be a percentage of the (average) peak value for the leakage current.

Thus, in some examples, the monitoring device 160 is adapted to determine the presence or absence of the fault at the LED lighting arrangement responsive to a peak value of the leakage signal sensed by the sensing circuit. More particularly, it has been recognized that a drop or change in the peak value of the leakage signal (e.g., within a certain moving time window) indicates the presence of a fault, e.g., a leakage in the LED lighting arrangement.

The ground leakage current may also be influenced by the power of the converter. In order to increase the accuracy of fault detection and prevent false detection, in some examples, the monitoring device is further configured to monitor an amplitude of the output power. This can be performed by monitoring a voltage provided at the output interface, e.g., across the output terminals T3, T4. The monitoring device may be configured to determine the presence of the fault occurring at the LED lighting arrangement responsive to the sensed leakage current being lower than the first threshold and the output power remaining stable (i.e., only undergoing insignificant changes, e.g., ±5%). This ensures that the detected fault is a fault in grounding of the return path of the LED lighting arrangement. This also reduces a likelihood that a fault will be erroneously identified when the leakage current changes due to a change in demand for the LED lighting arrangement, as this will naturally cause the output power to change and therefore not remain stable.

Although illustrated as separate elements, in some examples the monitoring device 160 and switch controller 129 are modules or functional elements of a single processor or controller. For instance, the LED driver may comprise a processor, such as a microprocessor, for performing control logic of the converter. The processor may perform the functions of the monitoring device 160 and the switch controller 129.

FIG. 2 is a circuit diagram illustrating an LED lighting arrangement 190 for use with the previously described LED driver.

In a normal LED luminaire, the LED lighting arrangement is configured to be placed in proximity with an external grounding structure 205 which is to be connected to the protective earth PE. One example of an external ground structure is a casing or housing for the LED lighting arrangement, i.e., a housing that encloses or encapsulates at least the LED lighting arrangement.

The LED lighting arrangement comprises an LED array (alternatively labelled an LED arrangement) comprising one or more LEDs. In the illustrated example, the LED array comprises only a single LED. However, in other examples, the LED array comprises a plurality of LEDs, e.g., a series or string of LEDs, an LED chip and so on.

The LED lighting arrangement 190 also comprises an LED input interface 210 connected to said LED array LED. The LED input interface 210 is configured to configured to connect to the output interface of the LED driver. In the illustrated example, the LED input interface 210 comprises a pair of terminals T5, T6 for connection to the output interface of the LED driver.

The LED array draws power from the LED input interface 210, having a power in line and a return out line connected to the LED input interface. Accordingly, the LED input interface comprises a positive terminal T5 (for the power line) and a negative terminal T6 (for the return line).

Most importantly, in order to make the ground leakage current in the LED driver is more distinguishable in presence or absence of the fault, the LED lighting arrangement further comprises an electricity leaking structure 220 which is electrically connected to the LED input interface 210. The electricity leaking structure is adapted to electrically connect the LED input interface 210 to the external grounding structure 205, to thereby leak a signal to said grounding structure, upon a fault at the LED lighting arrangement.

In particular, the electricity leaking structure may be positioned in close proximity to the external grounding structure, such that the presence of water/liquid/moisture between the electricity leaking structure and the external grounding structure (i.e., a leakage fault) will cause the LED input interface 210 to become electrically connected to the external grounding structure, and thereby the protective earth.

Thus, the electricity leaking structure is configured to electrically connect the LED input interface to the external grounding structure by an ingress of water or moisture accumulated at and contacting the electricity leaking structure and the external grounding structure. This effectively generates a low impedance to the protective earth within the whole lighting system (including the LED driver and the LED lighting arrangement). This low impedance will bypass/divert the original ground leakage current within the LED driver. Thus, the characteristics of the original (ground) leakage current will change).

In preferred examples, the electricity leakage structure is configured to be more proximate to the external grounding structure 205 than the LED array LED. This increases a likelihood that water or liquid ingress will be detected before the liquid reaches the LED array, which can cause significant damage to the LED array (e.g., if it is still powered at this point).

Preferably, the electricity leaking structure is coupled to the negative terminal T6 of the LED input interface. The voltage difference between the negative terminal T6 and the protective earth PE is likely to be less than the voltage difference between the positive terminal T5 and the protective earth PE (for conventional driving approaches). This reduces a risk of shocking if a fault occurs in the LED lighting arrangement 190.

In alternative examples, the electricity leaking structure is coupled to the positive terminal. Alternatively, the electricity leaking structure can connect to an intermediate LED if there are a plurality of LEDs.

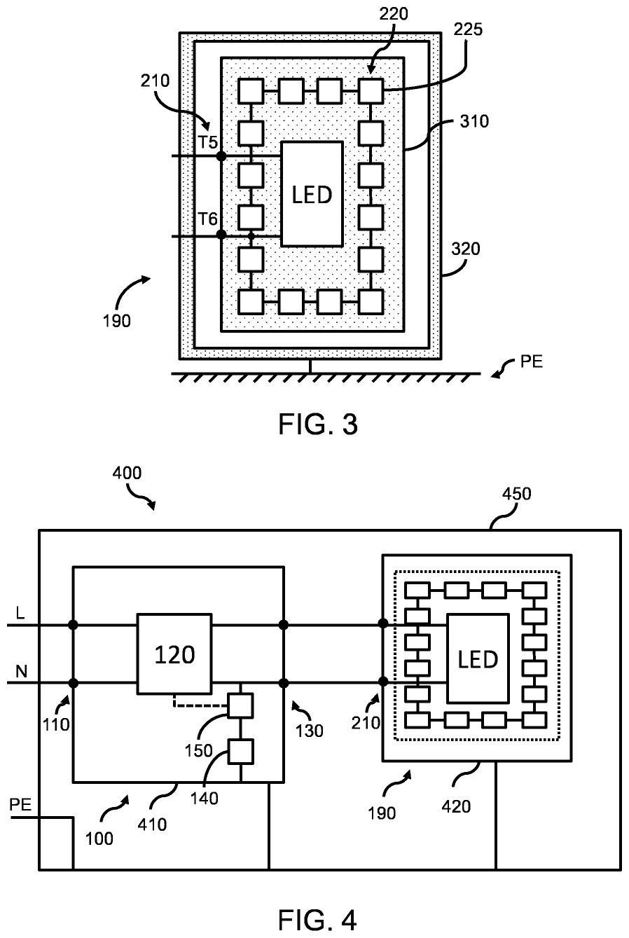

FIG. 3 schematically illustrates the structure of a proposed LED lighting arrangement. The LED lighting arrangement again comprises an LED array LED, the LED input interface 210, and the electricity leaking structure 220.

The LED lighting arrangement further comprises a substrate 310 configured to carry the LED array. Thus, the LED array is positioned on a first surface of the substrate.

The electricity leaking structure comprises one or more conductive pads 225 formed on the substrate 310, e.g., a plurality of conductive pads. Preferably, the electricity leaking structure 220 is positioned on the first surface of the substrate.

Preferably the one or more conductive pads are positioned along at least one edge. This allows for improved detection of water leakage or ingress from the at least one edge.

More preferably, the one or more conductive pads comprises a plurality of conductive pads positioned along or around a perimeter of the substrate. This allows for detection of water leakage towards the LED in all directions.

In some examples, the one or more conductive pads comprises a plurality of conductive pads positioned to surround the LED array LED. This increases a likelihood that water leakage fault will be detected before liquid reaches the LED array.

In some examples, the substrate comprises a conductive core configured to connect, in use, to the grounding structure. The conductive core is also originally designed for providing heat dissipation. The electricity leaking structure may be configured to electrically connect the input interface to the conductive core upon a fault at the LED lighting arrangement.

For instance, the electricity leaking structure may comprise one or more vias that mechanically, not yet electrically, connects a pad (of the electricity leaking structure) on an upper part of the substrate to the conductive core. A liquid that has reached to the substrate may fill this via and electrically connect the pad to the conductive core. The pad may be connected to the LED input interface 210, to thereby trigger the detection of a fault by the LED driver.

The external ground structure 320 of the LED lighting arrangement here comprises a housing for the LED lighting arrangement.

FIG. 4 illustrates a luminaire 400.

The luminaire comprises any herein disclosed LED driver 100 and any herein disclosed LED lighting arrangement 190.

The luminaire 400 also comprises a luminaire housing 450 configured to act as the (external) grounding structure. The grounding circuit 140 of the LED driver 100 is also connected to the luminaire housing 450. The luminaire housing may, for instance, be configured to connect to a protective earth PE provided by a mains power supply.

In some examples, the LED driver 100 comprises a driver housing 410 electrically coupled to the luminaire housing, e.g., screwed to the luminaire housing. The grounding circuit 140 may connect to the luminaire housing via the driver housing 410.

In some examples, the LED lighting arrangement 190 comprises an LED lighting housing 420 electrically coupled to the luminaire housing, e.g., screwed to the luminaire housing. In this approach, the LED lighting housing 420 also acts as (part of) the external grounding structure.

It has been previously mentioned how embodiments are particularly advantageous for lighting scenarios that are exposed to external environments, such as outdoor settings. In particular, any proposed luminaire may be an outdoor luminaire, being a luminaire designed or configured for use outdoors. A particularly advantageous example of such a luminaire is an automobile luminaire, being a luminaire configured for use with an automobile (e.g., car, van, lorry, motorbike etc.). This is because such luminaires are often exposed to outdoor weather (e.g., rain).

Variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality.

The mere fact that certain measures are recited in mutually different dependent claims does not indicate that a combination of these measures cannot be used to advantage.

If the term “adapted to” is used in the claims or description, it is noted the term “adapted to” is intended to be equivalent to the term “configured to”. If the term “arrangement” is used in the claims or description, it is noted the term “arrangement” is intended to be equivalent to the term “system”, and vice versa.

Any reference signs in the claims should not be construed as limiting the scope.

1. A LED driver for use with an LED lighting arrangement, the LED driver comprising:
an input interface configured to receive an input power;
a converter configured to convert the input power into an output power;
an output interface configured to connect to the LED lighting arrangement and to, when connected, provide the output power to the LED lighting arrangement;
a grounding circuit adapted to connect the converter to a protective earth and comprising a Y-capacitor connected to the converter and for connection with the protective earth and adapted to improve robustness of the LED driver to electromagnetic interference;
a sensing circuit adapted to sense a leakage signal, from the converter to the protective earth, through the Y-capacitor; and
a monitoring device adapted to determine the presence or absence of a fault at the LED lighting arrangement responsive to the sensed leakage signal sensed by the sensing circuit.

2. The LED driver of claim 1, wherein the monitoring device is adapted to:
determine the presence of a protective earth leakage fault occurring at the LED lighting arrangement responsive to the amplitude of the sensed leakage current being lower than a first threshold; and
determine the absence of a protective earth leakage fault occurring at the LED lighting arrangement responsive to the amplitude of the sensed leakage current being greater than the first threshold.

3. The LED driver of claim 2, wherein said first threshold is a percentage of the leakage signal flowing, from the converter to the protective earth, through the Y-capacitor in the absence of protective earth leakage fault occurring at the LED lighting arrangement.

4. The LED driver of claim 3, wherein the percentage is no more than seventy percent.

5. The LED driver of claim 2, wherein the monitoring device is adapted to determine the presence or absence of the fault at the LED lighting arrangement responsive to a peak value of the leakage signal sensed by the sensing circuit.

6. The LED driver of claim 2, wherein the monitoring device is configured to:
monitor an amplitude of the output power; and
the monitoring device is configured to determine the presence of the fault occurring at the LED lighting arrangement responsive to the sensed leakage current being lower than the first threshold and responsive to the output power remains stable.

7. The LED driver of claim 1, wherein the sensing circuit comprises a sensing resistor connected between the converter and the protective earth, wherein a voltage across the sensing resistor defines the leakage current.

8. The LED driver of claim 7, wherein the sensing circuit further comprises an operational amplifier configured to amplify a first voltage signal, being the voltage across the sensing resistor, to indicate the leakage current.

9. An LED lighting arrangement for use with the LED driver of claim 1, wherein the LED lighting arrangement is adapted to be placed in proximity with an external grounding structure which is to be connected to the protective earth, said LED lighting arrangement comprising:
an LED array comprising one or more LEDs, and
an LED input interface connected to said LED array and configured to connect to the output interface of the LED driver,
characterized by further comprising an electricity leaking structure electrically connected to the LED input interface, said electricity leaking structure being adapted to electrically connect the LED input interface to the external grounding structure, to thereby leak a signal to said external grounding structure, upon a fault at the LED lighting arrangement.

10. The LED lighting arrangement of claim 9, further comprising a substrate configured to carry the LED array, wherein:
the electricity leaking structure comprises one or more conductive pads formed on the substrate, wherein the conductive pads is different from terminals on the LED lighting arrangement and is electrically connected to the terminals, preferably wherein the one or more conductive pads are positioned along at least one edge, and more preferably along a perimeter, of the substrate.

11. The LED lighting arrangement of claim 9, wherein the electricity leaking structure is configured to electrically connect the LED input interface to the external grounding structure by an ingress of water or moisture accumulated at and contacting the electricity leaking structure and the external grounding structure.

12. The LED lighting arrangement of claim 9, wherein
the substrate comprises a conductive core configured to connect, in use, to the external grounding structure; and
the electricity leaking structure is configured to electrically connect the input interface to the conductive core upon a fault at the LED lighting arrangement,

13. The LED lighting arrangement of claim 9, wherein the LED input interface comprises a positive terminal and a negative terminal, wherein each conductive pad is electrically connected to either the positive terminal or the negative terminal.

14. A luminaire comprising:
the LED driver of claim 1;
the LED lighting arrangement; and
a luminaire housing configured to act as the external grounding structure, wherein the grounding circuit of the LED driver is connected to the luminaire housing.
